(19) United States
(12) Patent Application Publication
(10) Pub. No.: US 2021/0156912 A1
(43) Pub. Date: May 27, 2021

(54) Method For Boundary Scan Inspection And Functional Circuit Test Of Motherboard And Device Using The Same

(71) Applicants: Inventec (Pudong) Technology Corporation, Shanghai (CN); Inventec Corporation, Taipei City (TW)

(72) Inventor: Xiao-Yu Long, Shanghai (CN)

(21) Appl. No.: 16/743,723

(22) Filed: Jan. 15, 2020

(30) Foreign Application Priority Data
Nov. 26, 2019 (CN) 201911174048.3

(51) Int. Cl. G01R 31/3177; G06F 13/20; G06F 13/42

(52) U.S. Cl. CPC G01R 31/3177; G06F 13/20; G06F 2213/0042; G06F 2213/0026; G06F 13/4282

(57) ABSTRACT

A method and a device for a boundary scan inspection and a functional circuit test of a motherboard are disclosed. The method is applicable to a machine and includes steps of connecting a BSI fixture, a functional circuit test fixture and a hard drive to the motherboard, and making a host computer and the motherboard in communication connection with each other; performing, by the host computer, the boundary scan inspection on the motherboard based on the BSI fixture; performing, by a function test system installed in the hard drive, the functional circuit test on the motherboard based on the functional circuit test fixture. The boundary scan inspection and the functional circuit test can be integrated in the same machine, so as to facilitating to perform the boundary scan inspection and the functional circuit test on the motherboard, thereby speeding up test speed and reducing the number of the machines.

### CROSS-REFERENCE TO RELATED APPLICATION

This application claims the benefit of Chinese Application Serial No. 201911174048.3, filed Nov. 26, 2019, which is hereby incorporated herein by reference in its entirety.

### BACKGROUND OF THE INVENTION

### 1. Field of the Invention

The present invention relates to a method for testing a motherboard and a device thereof, and more particularly to a method and a device for a boundary scan inspection and a functional circuit test of a motherboard.

### 2. Description of the Related Art

The tests for motherboards of traditional servers, desktops and workstations can be classified into boundary scan inspection (BSI) and functional circuit test (FCT). The aforementioned boundary scan inspection (BSI) was developed in the 1990s. With the advent of large integrated circuits, printed circuit board manufacturing processes have developed towards small and thin size, so traditional ICT testing is unable to meet the test requirements of such products. A chip has many pins, components on a PCB are small, and a density of a board is particularly large, so it is hard to use probes for test. The boundary scan inspection has two major advantages, and one is to facilitate the fault localization of the chip, and quickly and accurately test whether the connection between the pins of two chips is reliable, so as to improve test efficiency; the other advantage is that the chip with JTAG interface has some pre-defined function modes built therein, and the chip can be set in a specific function mode by using a boundary scan channel, so that the system control flexibility and convenience in system design can be improved. The functional circuit tests can be classified into manual control function test, semi-automatic control function test, and fully automatic control function test according to different control schemes. The earliest functional circuit tests mainly include the manual control function test and semi-automatic control function test. For some simple function tests of the board under test, manual or semi-automatic testing solutions are sometimes used in consideration of simplifying design and reducing production costs. With the development of science and technology, in order to save production costs, most of the current functional circuit tests use fully automatic solutions. Another more general classification of the function tests is based on the type of controller for functional circuit testing. There are several control manners, including MCU control manner, embedded CPU control manner, PC control manner, PLC control manner, and so on, which are usually used in functional circuit tests.

However, performing a boundary scan inspection requires a professional automatic test machine, which is expensive.

In recent years, functional circuit test stations still exist for functional circuit tests, and expensive automatic test equipment is also required. Because some functions of these two automatic machines overlap, the test process using the two separate machines increase the cost of the machines. In addition, the boundary scan inspection and the functional circuit test must be performed on the scan test machine and the function test machine, respectively, and it wastes time and manpower.

Therefore, what is needed is to develop a solution in which the boundary scan inspection and the functional circuit test of the motherboard can be performed at the same time, the test process can be speeded up, and the number of machines can be reduced.

### SUMMARY OF THE INVENTION

An objective of the present invention is to provide a method for a boundary scan inspection and a functional circuit test of a motherboard and a device using the same, so as to solve the conventional technical problems and achieve the effect of performing the boundary scan inspection and the functional circuit test on the motherboard at the same time, and speeding up test speed and reduce the number of the machines.

In order to achieve the objective, the present invention provides a method for a boundary scan inspection and a functional circuit test of a motherboard, which includes steps of: connecting a boundary scan inspection (BSI) fixture, a functional circuit test fixture, and a hard drive to the motherboard, and making a host computer and the motherboard in communication connection with each other; using the host computer to perform the boundary scan inspection on the motherboard based on the BSI fixture; and using a function test system installed in the hard drive, to perform the functional circuit test on the motherboard based on the functional circuit test fixture.

In an embodiment of the present invention, the motherboard comprises a central processing unit (CPU) and a platform controller hub (PCH). A peripheral component interconnect express (PCIE) BSI fixture for the motherboard is connected to the central processing unit, a USB BSI fixture is connected to the PCH, an SATA BSI fixture is connected to the PCH, and a DIMM BSI fixture is connected to the CPU. The host computer performs a PCIE boundary scan inspection, a USB boundary scan inspection, an SATA boundary scan inspection, and a DIMM boundary scan inspection on the motherboard based on the PCIE BSI fixture for the motherboard, the USB BSI fixture, the SATA BSI fixture, and the DIMM BSI fixture, respectively.

In an embodiment of the present invention, the method further comprises steps of connecting a PCIE riser to the CPU, wherein the PCIE riser is configured to connect the PCIE BSI fixture for the motherboard which needs to be transferred; and using the host computer to perform the PCIE boundary scan inspection on the motherboard based on the PCIE BSI fixture for the motherboard which needs to be transferred.

In an embodiment of the present invention, the PCH is connected to an LED function test fixture, a battery function test fixture, and a display interface function test fixture through a USB interface, and the function test system installed in the hard drive performs an LED function test, a battery function test, and a display interface function test on the motherboard based on the LED function test fixture, the battery function test fixture, and the display interface function test fixture, respectively.

In an embodiment of the present invention, the method further includes a step of: using the functional circuit test fixture, which is directly connected to the motherboard, to perform the functional circuit test on the motherboard.

In order to implement the objective, the present invention further provides a device for a boundary scan inspection and a functional circuit test of a motherboard, the device is applicable to a machine and includes a host computer, a hard drive, a boundary scan inspection (BSI) fixture, and a functional circuit test fixture. The boundary scan inspection

(BSI) fixture is connected to the motherboard, the functional circuit test fixture is connected to the motherboard, the hard drive is connected to the motherboard, and the host computer is in communication connection with the motherboard. The host computer can perform the boundary scan inspection on the motherboard through the BSI fixture, and the functional circuit test fixture can perform the functional circuit test on the motherboard through a function test system installed in the hard drive.

In an embodiment of the present invention, the motherboard comprises a central processing unit (CPU) and a platform controller hub (PCH). A peripheral component interconnect express (PCIE) BSI fixture for the motherboard is connected to the CPU, a USB BSI fixture is connected to the PCH, an SATA BSI fixture is connected to the PCH, and a

DIMM BSI fixture is connected to the CPU. The host computer performs a PCIE boundary scan inspection, a USB boundary scan inspection, a SATA boundary scan inspection, and a DIMM boundary scan inspection on the motherboard based on the PCIE BSI fixture for the motherboard, the USB BSI fixture, the SATA BSI fixture, and the DIMM BSI fixture, respectively.

In an embodiment of the present invention, the device further includes a PCIE riser connected to the CPU, wherein the PCIE riser is configured to connect the PCIE BSI fixture for the motherboard which needs to be transferred, and the host computer performs the PCIE boundary scan inspection on the motherboard based on the PCIE BSI fixture for the motherboard which needs to be transferred.

In an embodiment of the present invention, the PCH is connected to an LED function test fixture, a battery function test fixture, and a display interface function test fixture through a USB interface, and the function test system installed in the hard drive performs an LED function test, a battery function test, and a display interface function test on the motherboard based on the LED function test fixture, the battery function test fixture, and the display interface function test fixture, respectively.

In an embodiment of the present invention, the functional circuit test fixture is directly connected to the motherboard to perform the functional circuit test on the motherboard.

According to the above-mentioned contents of the present invention, the method and device for the boundary scan and the functional circuit test of the motherboard have beneficial effects of performing the boundary scan inspection and the functional circuit test on the motherboard at the same time, speeding up test speed, and reducing the number of the machines.

### BRIEF DESCRIPTION OF THE DRAWINGS

The structure, operating principle and effects of the present invention will be described in detail by way of various embodiments which are illustrated in the accompanying drawings.

FIG. 1 is a flowchart of an embodiment of a method for a boundary scan inspection and a functional circuit test of a motherboard, according to the present invention.

FIG. 2A is a schematic structural view of an embodiment of a device for a boundary scan inspection and a functional circuit test of a motherboard, according to the present invention.

FIG. 2B is a schematic structural view of another embodiment of a device for a boundary scan inspection and a functional circuit test of a motherboard, according to the present invention.

### DETAILED DESCRIPTION OF THE PREFERRED EMBODIMENTS

The following embodiments of the present invention are herein described in detail with reference to the accompanying drawings. These drawings show specific examples of the embodiments of the present invention. These embodiments are provided so that this disclosure will be thorough and complete, and will fully convey the scope of the invention to those skilled in the art. It is to be acknowledged that these embodiments are exemplary implementations and are not to be construed as limiting the scope of the present invention in any way. Further modifications to the disclosed embodiments, as well as other embodiments, are also included within the scope of the appended claims. These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts.

It is to be acknowledged that, although the terms ‘first’, ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present disclosure. As used herein, the term “or” includes any and all combinations of one or more of the associated listed items.

It will be acknowledged that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present.

In addition, unless explicitly described to the contrary, the word “comprise”, “include” and “have”, and variations such as “comprises”, “comprising”, “includes”, “including”, “has” and “having” will be acknowledged to imply the inclusion of stated elements but not the exclusion of any other elements.

A method for a boundary scan inspection and a functional circuit test of a motherboard and a device using the same of the present invention can achieve the effect of facilitating to perform the boundary scan inspection and the functional circuit test on the motherboard at the same time, speeding up test speed, and reducing the number of the machines.

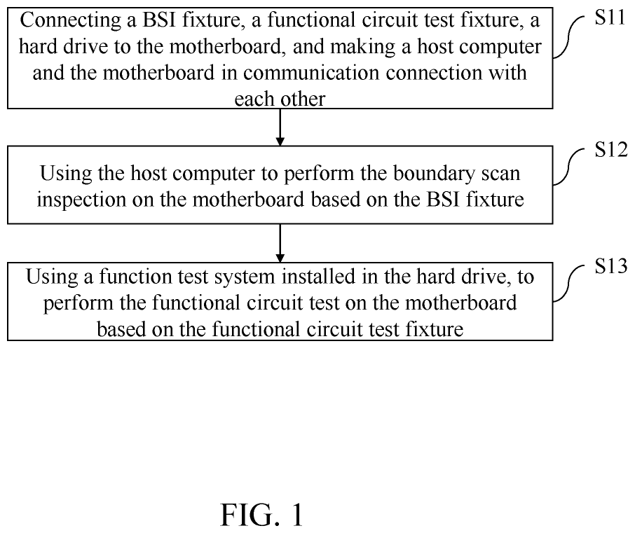

Please refer to FIG. 1, which is a flowchart of an embodiment of a method for a boundary scan inspection and a functional circuit test of a motherboard, according to the present invention. As shown in FIG. 1, an embodiment of the method for the boundary scan inspection and the functional circuit test of the motherboard include steps S11 to S13.

In the step S11, a boundary scan inspection (BSI) fixture, a functional circuit test fixture, and a hard drive are connected to the motherboard, and a host computer is in communication connection with the motherboard. It should be noted that the hard drive is called as a real HDD in the following paragraphs.

Particularly, the BSI fixture, the functional circuit test fixture and the real HDD are connected to the motherboard, and the host computer is in communication connection with the motherboard. The motherboard, the functional circuit test fixture and the BSI fixture can be disposed in the same machine, and the boundary scan inspection and the functional circuit test can be performed in the machine at the same time. In other words, in the original manner, the boundary scan inspection is performed in one machine, and the functional circuit test is performed in another machine; now, the boundary scan inspection and the functional circuit test can be combined to be performed in the same machine at the same time. Therefore, under the premise that the coverages of the boundary scan inspection and the functional circuit test are not changed, the number of the machines can be reduced, and the number of times for which the motherboard enters into and exits from the machine can also be reduced. Because the number of times for which the motherboard enters into and exits from the machine is reduced, while the boundary scan inspection and the functional circuit test are completed, the test time can be reduced, the labor cost and the space occupied by the machine can be reduced, and the number of the operators and the maintenance cost of the machine can also be reduced. Originally, the boundary scan inspection and the functional circuit test are performed separately, and it needs to install the test fixture for two times, and control the test fixture to enter and exit from the machine, and there are test risks in the process. Therefore, when the boundary scan inspection and the functional circuit test can be completed in the same machine, the times of occupation of the machine can be reduced by one, and the times of installation and detachment of the test fixture can also be reduced by one, so as to reduce 50% of the impact risk and further improve the test pass rate.

In the step S12, the host computer can perform the boundary scan inspection on the motherboard based on the BSI fixture.

Particularly, the host computer is a device used to control the machine, execute the boundary scan inspection of the motherboard. The host computer can be a computer capable of directly issuing a control command to the motherboard.

Particularly, the motherboard comprises a central processing unit (CPU) and a platform controller hub (PCH). A peripheral component interconnect express (PCIE) BSI fixture for the motherboard is connected to the CPU, a USB BSI fixture is connected to the PCH, an SATA BSI fixture is connected to the PCH, and a DIMM BSI fixture is connected to the CPU. The host computer can perform a PCIE boundary scan inspection, a USB boundary scan inspection, an SATA boundary scan inspection, and a DIMM boundary scan inspection on the motherboard based on the PCIE BSI fixture for the motherboard, the USB BSI fixture, the SATA BSI fixture, and the DIMM BSI fixture, respectively. Particularly, the real HDD, the BSI fixture, and the functional circuit test fixture are connected to the motherboard through plug manners, but do not included in the motherboard. The motherboard includes the

CPU and the PCH. The PCIE BSI fixture for the motherboard is connected to the CPU, and the PCIE BSI fixture for the motherboard is a fixture used to perform the boundary scan inspection on the PCIE of the motherboard. The PCIE BSI fixture for the motherboard is used to perform the boundary scan inspection on the PCIE of the motherboard by connecting with the CPU. The USB BSI fixture is a fixture used to perform the boundary scan inspection on the USB of the motherboard; the USB BSI fixture is used to perform the boundary scan inspection on the USB of the motherboard by connecting with the PCH. The SATA BSI fixture is a fixture used to perform the boundary scan inspection on the SATA of the motherboard; the SATA BSI fixture is used to perform the boundary scan inspection on the SATA of the motherboard by connecting with the PCH. The DIMM BSI fixture is a fixture used to perform the boundary scan inspection on the DIMM; the DIMM BSI fixture is used to perform the boundary scan inspection on the DIMM of the motherboard by connecting with the CPU.

Particularly, in an embodiment, a PCIE riser can be connected to the CPU and configured to connect the PCIE BSI fixture for the motherboard which needs to be transferred. The host computer can perform the PCIE boundary scan inspection on the motherboard based on the PCIE BSI fixture for the motherboard which needs to be transferred. The PCIE BSI fixture for the motherboard needs to be connected to the CPU of the motherboard via the PCIE riser, so as to perform the boundary scan inspection on the PCIE of the motherboard.

In the step S13, the function test system installed in the real HDD can perform the functional circuit test on the motherboard based on the functional circuit test fixture.

Particularly, the PCH is connected to an LED function test fixture (such as an LED sensor), a battery function test fixture (such as Arduino), and a display interface function test fixture (such as video graphics array (VGA) board), via the USB interface. The function test system installed in the real HDD can perform the LED function test, the battery function test and the display interface function test on the motherboard, based on the LED function test fixture, the battery function test fixture, and the display interface function test fixture, respectively. The battery function test is a function test for CMOS battery voltage of the motherboard, the LED function test is a test for the LED function of the motherboard, and the display interface function test is a function test for the display interface of the motherboard.

Particularly, the PCH is connected to a keyboard and a network card with the USB interface via the USB interface, and used to perform a keyboard function test and a network function test on the motherboard.

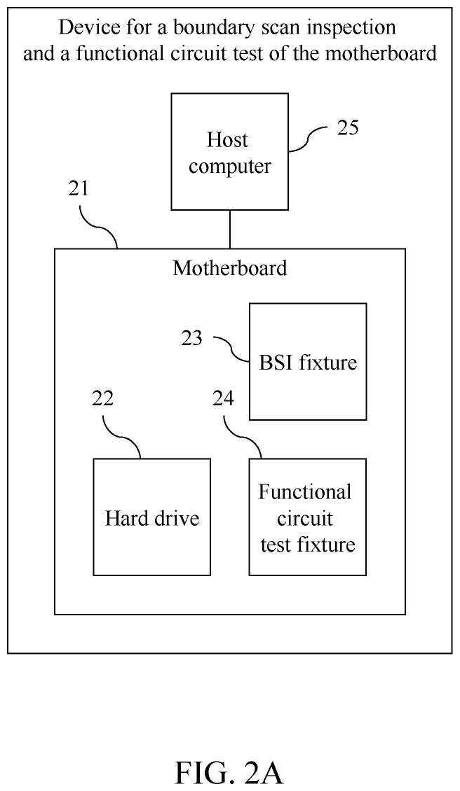

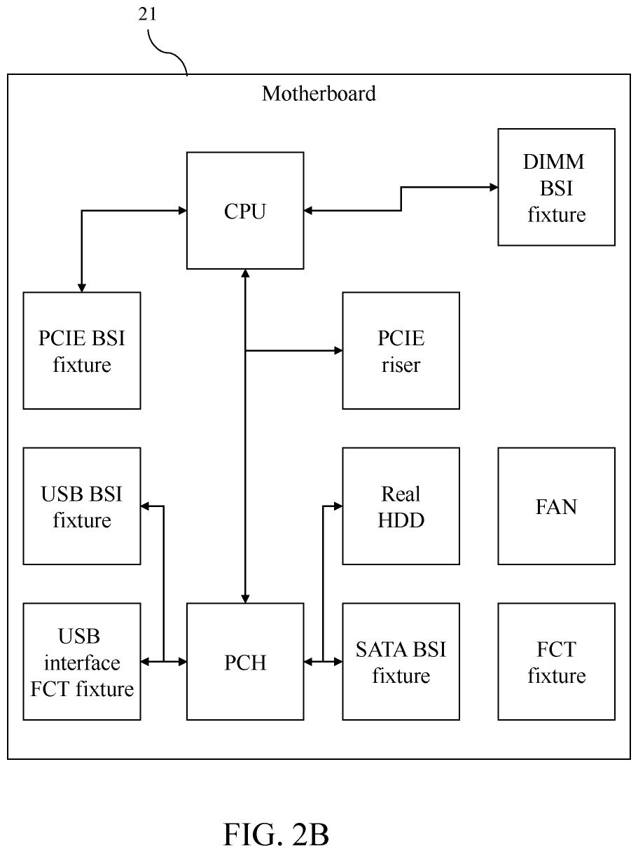

Particularly, the functional circuit test fixture is further directly connected to the motherboard, and used to perform the functional circuit test on the motherboard. For example, a fan function fixture, which is labeled as “FAN” in FIG. 2B, can be directly connected to the motherboard and used to perform a fan function test on the motherboard.

Particularly, the test system corresponding to the functional circuit test must be installed in the real HDD connected to the PCH.

Particularly, the method for the boundary scan inspection and the functional circuit test of the motherboard includes steps of: connecting the BSI fixture to the motherboard, connecting the functional circuit test fixture to the motherboard, connecting the real HDD to the motherboard, and making the host computer and the motherboard in communication connection with each other; disposing the BSI fixture, the motherboard, the functional circuit test fixture and the real HDD on the machine; using the host computer to control the machine; using the host computer to read a serial number, which is also abbreviated as SN code or Serial No. and defined as a product serial number, of the motherboard, and perform the boundary scan inspection on the motherboard based on the BSI fixture; storing a test result of the boundary scan inspection in a preset management system, such as the manufacturing execution system (MES); according to the serial number (SN code) of the motherboard obtained from the host computer, using the function test system installed in the real HDD to perform the functional circuit test on the corresponding motherboard based on the functional circuit test fixture, and storing a functional circuit test result in the preset management system;

and transmitting information indicative of completion of the functional circuit test to the host computer, so as to use the host computer to control the machine to stop testing. In this embodiment, the motherboard and the host computer are in communication connection via a serial port, to transmit the SN code of the motherboard and notify the host computer of completion of the boundary scan inspection and the functional circuit test.

Please refer to FIG. 2A, which is a schematic structural view of an embodiment of a device for a boundary scan inspection and a functional circuit test of a motherboard, according to the present invention. As shown in FIG. 2, in an embodiment, the device for the boundary scan inspection and the functional circuit test of the motherboard 21 comprises a host computer 25, a real HDD 22, a BSI fixture 23, and a functional circuit test fixture 24.

The BSI fixture 23, the functional circuit test fixture 24 and the real HDD 22 are connected to the motherboard 21, and the host computer 25 is in communication connection with the motherboard 21. The host computer 25 performs the PCIE boundary scan inspection on the motherboard 21 through the BSI fixture 23. The functional circuit test fixture 24 performs the functional circuit test on the motherboard 21 through the function test system installed in the real HDD 22.

Particularly, the motherboard 21 comprises a central processing unit (CPU) and a platform controller hub (PCH). A PCIE BSI fixture 23 for the motherboard 21 is connected to the CPU, a USB BSI fixture 23 is connected to the PCH, an SATA BSI fixture 23 is connected to the PCH, and a DIMM BSI fixture 23 is connected to the CPU. The host computer 25 performs the PCIE boundary scan inspection, the USB boundary scan inspection, the SATA boundary scan inspection, and the DIMM boundary scan inspection on the motherboard 21, respectively, through the PCIE BSI fixture 23 for the motherboard 21, the USB BSI fixture 23, the SATA BSI fixture 23, and the DIMM BSI fixture 23.

Particularly, a PCIE riser can be used to connect to the central processing unit, and the PCIE riser is configured to connect the PCIE BSI fixture 23 for the motherboard 21 which needs to be transferred. The host computer 25 can perform the PCIE boundary scan inspection on the motherboard 21 through the PCIE BSI fixture 23 for the motherboard 21, which needs to be transferred.

Particularly, the PCH can be connected to the LED function test fixture 24, the battery function test fixture 24, and the display interface function test fixture 24 via the USB interface. The function test system installed in the real HDD 22 can perform an LED function test, a battery function test, and a display interface function test on the motherboard 21 through the LED function test fixture 24, the battery function test fixture 24, and the display interface function test fixture 24, respectively.

Particularly, the functional circuit test fixture 24 can be directly connected to the motherboard 21 to perform the functional circuit test on the motherboard 21.

Particularly, the motherboard 21, the real HDD 22, the BSI fixture 23 and the functional circuit test fixture 24 are disposed in the same machine, so that the boundary scan inspection and the functional circuit test can be completed in the same machine.

Please refer to FIG. 2B, which is a schematic structural view of another embodiment of a device for a boundary scan inspection and a functional circuit test of a motherboard, according to the present invention. The components of the device for the boundary scan inspection and the functional circuit test of the motherboard are described in following paragraphs with reference to FIG. 2B.

Particularly, as shown in FIG. 2B, the motherboard comprises a CPU, and a PCH. A PCIE BSI fixture for the motherboard is connected to the CPU, a USB BSI fixture is connected to the PCH, a SATA BSI fixture is connected to the PCH, and a DIMM BSI fixture is connected to the CPU. The host computer performs the PCIE boundary scan inspection, the USB boundary scan inspection, the SATA boundary scan inspection, and the DIMM boundary scan inspection on the motherboard through the PCIE BSI fixture for the motherboard, the USB BSI fixture, the SATA BSI fixture, and the DIMM BSI fixture, respectively. Particularly, the real HDD, the BSI fixture, and the functional circuit test fixture are connected through plug manners, but not included in the motherboard. The motherboard includes the CPU and the PCH. The PCIE BSI fixture for the motherboard is connected to the CPU, and is a fixture of performing the boundary scan inspection on the PCIE of the motherboard, and in an embodiment, the PCIE BSI fixture performs the boundary scan inspection on the PCIE of the motherboard by connecting with the CPU. The USB BSI fixture is a fixture for performing the boundary scan inspection on the USB of the motherboard, and is used to perform the boundary scan inspection on the USB of the motherboard by connecting with the PCH. The SATA BSI fixture is a fixture for performing the boundary scan inspection on the serial advanced technology attachment (SATA) of the motherboard, and performs the boundary scan inspection on the SATA of the motherboard by connecting with the PCH. The DIMM BSI fixture is a fixture for performing the boundary scan inspection on the dual-inline-memory-modules (DIMM) of the motherboard, and performs the boundary scan inspection on the DIMM of the motherboard by connecting with the CPU. Particularly, a PCIE riser can be connected to the CPU and used to connect the PCIE BSI fixture for the motherboard which needs to be transferred. The host computer can perform the

PCIE boundary scan inspection on the motherboard based on the PCIE BSI fixture for the motherboard which needs to be transferred. The PCIE BSI fixture for the motherboard must be connected to the CPU of the motherboard via the PCIE riser, so as to perform the boundary scan inspection on the PCIE of the motherboard. Particularly, the PCH is connected to the LED function test fixture (such as an LED sensor), a battery function test fixture (such as Arduino), and a display interface function test fixture (such as a video graphics array board (VGA board)), through the USB interface. The function test system installed in the real HDD, can perform the LED the function test, the battery function test, and the display interface function test on the motherboard based on the LED function test fixture, the battery function test fixture, and the display interface function test fixture, respectively. The battery function test is a function test for a CMOS battery voltage of the motherboard, the LED function test is a test for an LED function of the motherboard, and the display interface function test is a function test for a display interface of the motherboard. Particularly, the PCH is connected to, via the USB interface, a keyboard and a network card with USB interface, so as to perform the keyboard function test and the network function test on the motherboard. Particularly, a functional circuit test fixture can be directly connected to the motherboard to perform at least one functional circuit test on the motherboard, for example, the fan function fixture can be directly connected to the motherboard to perform a fan function test on the motherboard.

It is to be noted that structures and operational principles of the host computer 25, the motherboard 21, the real HDD 22, the BSI fixture 23 and the functional circuit test fixture 24 correspond, one by one, to the aforementioned steps of the above-mentioned method for the boundary scan inspection and the functional circuit test of the motherboard, so the detailed descriptions are not repeated herein.

According to above-mentioned contents, the method and device for the boundary scan inspection and the functional circuit test of the motherboard according to the present invention facilitates to perform the boundary scan inspection and the functional circuit test on the motherboard at the same time, so as to speed up test speed and further reduce the number of the machines. As a result, the method and device of the present invention can effectively overcome the conventional technical problem and promote the industrial practicability.

The present invention disclosed herein has been described by means of specific embodiments. However, numerous modifications, variations and enhancements can be made thereto by those skilled in the art without departing from the spirit and scope of the disclosure set forth in the claims.

What is claimed is:

1. A method for a boundary scan inspection and a functional circuit test of a motherboard, applicable to a machine, and comprising:
connecting a boundary scan inspection (BSI) fixture, a functional circuit test fixture, a hard drive to the motherboard, and making a host computer and the motherboard in communication connection with each other;
using the host computer to perform the boundary scan inspection on the motherboard based on the BSI fixture; and
using a function test system installed in the hard drive, to perform the functional circuit test on the motherboard based on the functional circuit test fixture.

2. The method according to claim 1, wherein the motherboard comprises a central processing unit (CPU) and a platform controller hub (PCH), and a peripheral component interconnect express (PCIE) BSI fixture for the motherboard is connected to the CPU, a USB BSI fixture is connected to the PCH, an SATA BSI fixture is connected to the PCH, a DIMM BSI fixture is connected to the CPU, and the host computer performs a PCIE boundary scan inspection, a USB boundary scan inspection, an SATA boundary scan inspection, and a DIMM boundary scan inspection on the motherboard based on the PCIE BSI fixture for the motherboard, the USB BSI fixture, the SATA BSI fixture, and the DIMM BSI fixture, respectively.

3. The method according to claim 2, further comprising:
connecting a PCIE riser to the CPU, wherein the PCIE riser is configured to connect the PCIE BSI fixture for the motherboard which needs to be transferred; and
using the host computer to perform the PCIE boundary scan inspection on the motherboard based on the PCIE BSI fixture for the motherboard which needs to be transferred.

4. The method according to claim 2, wherein the PCH is connected to an LED function test fixture, a battery function test fixture, and a display interface function test fixture through a USB interface, and the function test system installed in the hard drive performs an LED the function test, a battery function test, and a display interface function test on the motherboard based on the LED function test fixture, the battery function test fixture, and the display interface function test fixture, respectively.

5. The method according to claim 2, further comprising:
using the functional circuit test fixture, which is directly connected to the motherboard, to perform the functional circuit test on the motherboard.

6. A device for a boundary scan inspection and a functional circuit test of a motherboard, applicable to a machine, and comprising:
a hard drive connected to the motherboard;
a boundary scan inspection (BSI) fixture connected to the motherboard;
a functional circuit test fixture connected to the motherboard, and configured to perform the functional circuit test on the motherboard through a function test system installed in the hard drive; and
a host computer connected to the motherboard in communication, and configured to perform the boundary scan inspection on the motherboard through the BSI fixture.

7. The device according to claim 6, wherein the motherboard comprises a CPU and a PCH, and a PCIE BSI fixture for the motherboard is connected to the CPU, a USB BSI fixture is connected to the PCH, an SATA BSI fixture is connected to the PCH, and a DIMM BSI fixture is connected to the CPU, and the host computer performs a PCIE boundary scan inspection, a USB boundary scan inspection, a SATA boundary scan inspection, and a DIMM boundary scan inspection on the motherboard based on the PCIE BSI fixture for the motherboard, the USB BSI fixture, the SATA BSI fixture, and the DIMM BSI fixture, respectively.

8. The device according to claim 7, further comprising a PCIE riser connected to the CPU, wherein the PCIE riser is configured to connect the PCIE BSI fixture for the motherboard which needs to be transferred, and the host computer performs the PCIE boundary scan inspection on the motherboard based on the PCIE BSI fixture for the motherboard which needs to be transferred.

9. The device according to claim 7, wherein the PCH is connected to an LED function test fixture, a battery function test fixture, and a display interface function test fixture through a USB interface, and the function test system installed in the hard drive performs an LED function test, a battery function test, and a display interface function test on the motherboard based on the LED function test fixture, the battery function test fixture, and the display interface function test fixture, respectively.

10. The device according to claim 7, wherein the functional circuit test fixture is directly connected to the motherboard to perform the functional circuit test on the motherboard.
